(19) United States
(12) Patent Application Publication
(10) Pub. No.: US 2025/0364780 A1
(43) Pub. Date: Nov. 27, 2025

(54) CAP MEMBER, METHOD OF MANUFACTURING SAME, AND LIGHT EMITTING DEVICE

(71) Applicant: NICHIA CORPORATION, Tokushima (JP)

(72) Inventors: Shota MURAKAMI, Anan-shi (JP); Takuya HASHIMOTO, Tokushima-shi (JP)

(21) Appl. No.: 19/212,031

(22) Filed: May 19, 2025

(30) Foreign Application Priority Data
May 23, 2024 (JP) 2024-084328

(51) Int. Cl. H01S 5/02208; H01S 5/02218; H01S 5/02257; H01S 5/183

(52) U.S. Cl. CPC H01S 5/02208; H01S 5/02218; H01S 5/02257; H01S 5/183

(57) ABSTRACT

A cap member includes a frame-shaped light shielding member having an upper surface, a lower surface, and an inner lateral surface connecting inner edges of the upper and lower surfaces; a light transmissive member bonded to an upper surface side of the light shielding member and closing an opening of the light shielding member; and a metal film on the lower surface. The inner lateral surface includes: a first region extending from the inner edge of the upper surface toward the center of an upper-surface-side opening, defined by inner edges of the upper surface, when viewed from above, and a second region extending from the inner edge of the lower surface toward the center of a lower-surface-side opening, defined by inner edges of the lower surface, when viewed from below. The metal film does not reach the inner lateral surface of the light shielding member.

### CROSS-REFERENCE TO RELATED APPLICATION

This application claims priority to Japanese Patent Application No. 2024-084328 filed on May 23, 2024, the disclosure of which is hereby incorporated by reference in its entirety.

### BACKGROUND

The present disclosure relates to a cap member, a method of manufacturing the same, and a light emitting device.

A cover member for use as a cap of an electronic device, such as a light emitting device, has been known. For example, a cover member that includes a spacer having a through hole and a cover disposed on the spacer so as to close the through hole of the spacer has been proposed (e.g., see Japanese Patent Publication No. 2019-62029).

### SUMMARY

One object of the present disclosure is to provide a cap member capable of providing a hermetic seal and miniaturizing an electronic device, such as a light emitting device, and a method of manufacturing the same. Another object of the present disclosure is to provide a light emitting device having the cap member.

A cap member according to one embodiment of the present disclosure includes a frame-shaped light shielding member having an upper surface, a lower surface, and one or more inner lateral surfaces connecting a corresponding one of one or more inner edges of the upper surface and a corresponding one of one or more inner edges of the lower surface; a light transmissive member bonded to an upper surface side of the light shielding member and closing an opening of the light shielding member; and a metal film disposed on the lower surface of the light shielding member. An inner lateral surface of the one or more inner lateral surfaces of the light shielding member include: a first region extending from the inner edge of the upper surface of the light shielding member toward the center of an upper-surface-side opening, defined by the one or more inner edges of the upper surface, when viewed from above the cap member, and a second region extending from the inner edge of the lower surface of the light shielding member toward the center of a lower-surface-side opening, defined by the one or more inner edges of the lower surface, when viewed from below the cap member. The metal film does not reach the inner lateral surface of the light shielding member including the first region and the second region.

A method of manufacturing a cap member according to one embodiment of the present disclosure includes: providing a sheet-shaped light shielding member; disposing, on a first principal surface of the light shielding member, a metal film having a first opening in which the first principal surface is exposed; disposing, on a second principal surface of the light shielding member, a cover film having a second opening in which the second principal surface is exposed, the second opening formed at a position that overlaps the first opening when viewed from the first principal surface side; forming a through hole that extends from the first opening to the second opening by etching the light shielding member from the first principal surface side and the second principal surface side; and disposing, on the second principal surface of the light shielding member, a sheet-shaped light transmissive member that closes the through hole, in the step of forming the through hole, the through hole being formed as a result of allowing a first recess formed from the metal film side and a second recess formed from the cover film side to be connected with each other.

A light emitting device according to one embodiment of the present disclosure includes: a substrate; a light emitting element disposed on an upper surface of the substrate; and a cap member, in which a lower surface of the light shielding member is bonded to a peripheral portion of the upper surface of the substrate, and the light emitting element is sealed by the substrate and the cap member.

According to an embodiment of the present disclosure, a cap member capable of providing a hermetic seal and miniaturizing an electronic device, such as a light emitting device, and a method of manufacturing the same can be provided. Moreover, a light emitting device having such a cap member can be provided.

### BRIEF DESCRIPTION OF THE DRAWINGS

FIG. 1 is a cross-sectional view illustrating a cap member according to a first embodiment.

FIG. 2 is a top view of a light shielding member which is a constituent of the cap member shown in FIG. 1.

FIG. 3 is a bottom view of the light shielding member which is a constituent of the cap member shown in FIG. 1.

FIG. 4 is a partial cross-sectional view of the light shielding member which is a constituent of the cap member shown in FIG. 1.

FIG. 5A is a top view (1) illustrating a method of manufacturing a cap member according to the first embodiment.

FIG. 5B is a top view (2) illustrating the method of manufacturing the cap member according to the first embodiment.

FIG. 5C is a cross-sectional view (3) illustrating the method of manufacturing the cap member according to the first embodiment.

FIG. 5D is a cross-sectional view (4) illustrating the method of manufacturing the cap member according to the first embodiment.

FIG. 5E is a cross-sectional view (5) illustrating the method of manufacturing the cap member according to the first embodiment.

FIG. 5F is a cross-sectional view (6) illustrating the method of manufacturing the cap member according to the first embodiment.

FIG. 5G is a cross-sectional view (7) illustrating the method of manufacturing the cap member according to the first embodiment.

FIG. 5H is a cross-sectional view (8) illustrating the method of manufacturing the cap member according to the first embodiment.

FIG. 6A is a top view (1) illustrating a first variation of the method of manufacturing a cap member according to the first embodiment.

FIG. 6B is a cross-sectional view (2) illustrating the first variation of the method of manufacturing the cap member according to the first embodiment.

FIG. 6C is a cross-sectional view (3) illustrating the first variation of the method of manufacturing the cap member according to the first embodiment.

FIG. 6D is a cross-sectional view (4) illustrating the first variation of the method of manufacturing the cap member according to the first embodiment.

FIG. 6E is a cross-sectional view (5) illustrating the first variation of the method of manufacturing the cap member according to the first embodiment.

FIG. 6F is a cross-sectional view (6) illustrating the first variation of the method of manufacturing the cap member according to the first embodiment.

FIG. 7 is a cross-sectional view illustrating a second variation of the method of manufacturing the cap member according to the first embodiment.

FIG. 8 is a cross-sectional view (1) illustrating a light emitting device according to a second embodiment.

FIG. 9 is a cross-sectional view (2) illustrating the light emitting device according to the second embodiment.

### DETAILED DESCRIPTION

Forms of implementing the present disclosure will be explained below with reference to the accompanying drawings. In the description below, terms indicating specific directions or positions (e.g., “upward/upper,” “downward/lower,” or terms including these) might be used as needed. These terms, however, are merely used in order to make the present invention described with reference to the drawings more easily understood, and the meanings of these terms are not meant to excessively restrict the technical scope of the present invention. For example, the use of the term “upper surface” does not mean that the invention must be used such that it always faces upwards. The parts or members denoted by the same reference numerals in multiple drawings represent the same or equivalent parts or members.

In the present disclosure, a polygon, such as a triangle, rectangle, or the like, includes shapes having modified portions, such as rounded corners, beveled corners, or the like. Moreover, the location of such a modified portion is not limited to a corner (an end of a side) of a polygon. Rather, a shape with modified portion in the intermediate portion of a side will similarly be referred to as a polygon. In other words, any polygon-based shape subjected to partial modification should be understood to be included in the interpretation of a “polygon” described in the present disclosure.

This similarly applies to words expressing specific shapes besides polygons, such as a trapezoid, circle, projection, recess, or the like. This further applies to words related to sides that make up a shape. In other words, even when the end or intermediate portion of a side is modified, the interpretation of a “side” includes the modified portion. In the case of distinguishing a “polygon” or “side” without partial modification from a shape with a modified portion, the word “strict,” for example, is added to describe the shape, for example, a “strict rectangle.”

The embodiments described below are examples of cap members or the like provided to give shape to the technical ideas of the present invention, and the invention is not limited to those described below. The dimensions, materials, shapes, and relative positions of the constituents of the embodiments are merely provided as explanatory examples, and not intended to limit the scope of the present invention to those described below unless otherwise specifically noted. The content of one embodiment is applicable to other embodiments and variations. The sizes of and positional relationships between the members shown in each drawing may be exaggerated for clarity of explanation. Moreover, a schematic drawing omitting certain elements may be used, or only a cut end surface might be used as a cross-sectional view so as not to make the drawing excessively complicated.

### First Embodiment

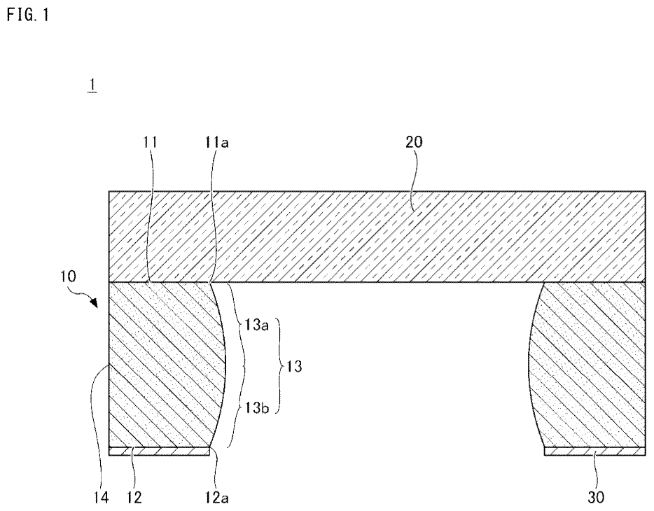

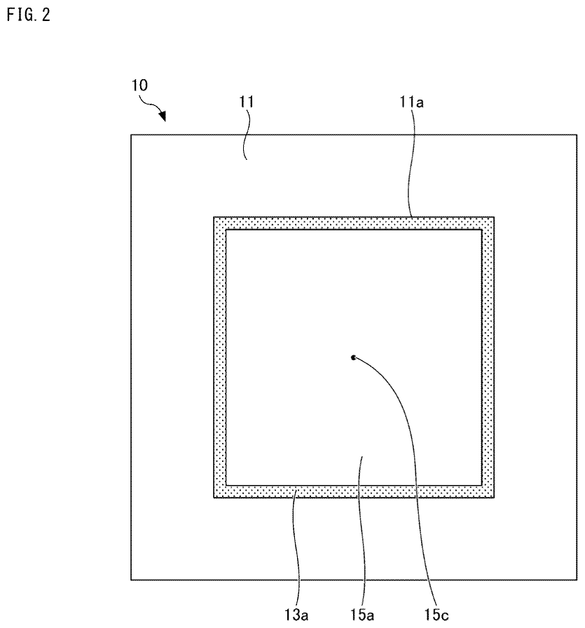

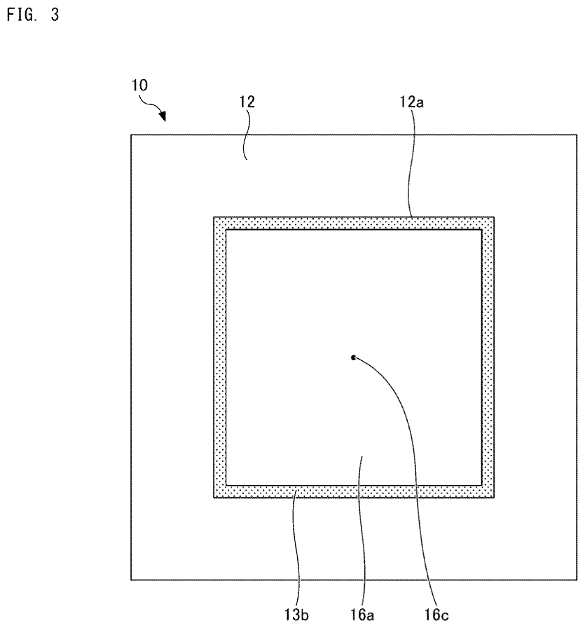

FIG. 1 is a cross-sectional view illustrating a cap member 1 according to a first embodiment. FIG. 2 is a top view of a light shielding member which is a constituent of the cap member shown in FIG. 1. FIG. 3 is a bottom view of the light shielding member which is a constituent member of the cap member shown in FIG. 1.

The cap member 1 according to the first embodiment has a light shielding member 10 and a light transmissive member 20. In the example shown in the drawings, the cap member 1 further includes a metal film 30. The cap member 1 does not necessarily have a metal film 30.

### Light Shielding Member 10

The light shielding member 10 is a frame-shaped member which includes an upper surface 11, a lower surface 12, and an inner lateral surface 13 which connects an inner edge 11a of the upper surface 11 and an inner edge 12a of the lower surface 12. The light shielding member is made of, for example, silicon. A thickness of the light shielding member 10 is not particularly limited, and is about 0.3 mm to 1 mm, for example. The term “light shielding” here refers to the property of not transmitting light, referring to a transmittance of 20% or lower for light having a given peak wavelength. The light shielding property may be achieved by utilizing a light absorbing property and a light reflecting property besides a light blocking property.

The light shielding member 10 has a rectangular frame shape when viewed from above, for example. The inner edges 11a of the upper surface 11 form a rectangle when viewed from above, for example. The inner edges 11a of the upper surface 11 define an upper-surface-side opening 15a. The inner edges 12a of the lower surface 12 form a rectangle when viewed from below, for example. The inner edges 12a of the lower surface 12 define the lower-surface-side opening 16a. The inner edges 11a of the upper surface 11 and the inner edges 12a of the lower surface 12 are positioned to overlap when viewed from above and below, for example. Rectangles may include a square unless specifically stated to exclude a square.

The outer edges of the upper surface 11 form a rectangle that encloses the inner edges 11a when viewed from above, for example. The outer edges of the lower surface 12 form a rectangle that encloses the inner edges 12a when viewed from below, for example. The outer edges of the upper surface 11 and the outer edges of the lower surface 12 are positioned to overlap when viewed from above and below, for example. The light shielding member 10 includes an outer lateral surface 14 connecting an outer edge of the upper surface 11 and an outer edge of the lower surface 12. The light shielding member 10 has one or more outer lateral surfaces 14. In the example shown in the drawings, the light shielding member 10 has four rectangular outer lateral surfaces 14.

In the example shown in the drawings, the lower surface 12 is disposed parallel to the upper surface 11. The lower surface 12 does not have to be parallel to the upper surface 11. In the example shown in the drawings, each of the outer lateral surfaces 14 is orthogonal to the upper surface 11. The outer lateral surfaces 14 do not have to be orthogonal to the upper surface 11.

The inner lateral surface 13 has a first region 13a that extends from the inner edge 11a of the upper surface 11 toward a center 15c of the upper-surface-side opening 15a when viewed from above. The first region 13a extends from the inner edge 11a of the upper surface 11 toward the center 15c of the upper-surface-side opening 15a throughout the length of the inner edge 11a of the upper surface 11 when viewed from above. The light shielding member 10 includes one or more inner lateral surfaces 13. In the example shown in the drawings, the light shielding member 10 has four inner lateral surfaces 13. The first region 13a may be present in only one of the inner lateral surfaces 13, or in each of the inner lateral surfaces 13.

Furthermore, an inner lateral surface 13 has a second region 13b that extends from the inner edge 12a of the lower surface 12 toward a center 16c of the lower-surface-side opening 16a when viewed from below. The second region 13b extends from the inner edge 12a of the lower surface 12 toward the center 16c of the lower-surface-side opening 16a throughout the length of the inner edge 12a of the lower surface 12 when viewed from below. The second region 13b may be present in only one of the inner lateral surfaces 13, or in each of the inner lateral surfaces 13.

The inner lateral surface 13 is curved in a cross section that is orthogonal to the upper surface 11 of the light shielding member 10, for example. The inner lateral surface 13 may include a straight portion in the cross section that is orthogonal to the upper surface 11 of the light shielding member 10. In FIG. 2 and FIG. 3, the first regions 13a and the second regions 13b are shown using a dot pattern for explanatory purposes.

At least a portion of the one or more inner edges of the light shielding member 10 do not overlap the one or more inner edges 11a of the upper surface 11 when viewed from above. In the example shown in the drawings, the inner edges of the light shielding member 10 do not overlap the inner edges 11a of the upper surface 11 at all when viewed from above. The inner edges of the light shielding member 10 do not overlap the inner edges 12a of the lower surface 12 at least in part when viewed from below. In the example shown in the drawings, the inner edges of the light shielding member 10 do not overlap the inner edges 12a of the lower surface 12 at all when viewed from below.

The inner lateral surface 13 is not located outward of a corresponding inner edge 11a of the upper surface 11 when viewed from above. The inner lateral surface 13 is not located outward of a corresponding inner edge 12a of the lower surface 12 when viewed from below.

The maximum width from an inner edge 11a of the upper surface 11 to a corresponding inner edge of the light shielding member 10 when viewed from above is the same as the maximum width from an inner edge 12a of the lower surface 12 to a corresponding inner edge of the light shielding member 10 when viewed from below. The term “same” here encompasses a difference up to 5 μm.

A width, being the minimum distance from an outer edge to the inner edge 11a, of the upper surface 11 when viewed from above and a width, being the minimum distance from an outer edge to the inner edge 12a, of the lower surface 12 when viewed from below may be the same as or different from each other.

The light shielding member 10 can be regarded as a frame member. While the term “light shielding member 10” refers to a member having a light shielding property, the term “frame member” itself does not indicate that the member essentially has a light shielding property.

### Light Transmissive Member 20

A light transmissive member 20 has an upper surface and a lower surface. The light transmissive member 20 has, for example, a flat sheet shape. The upper surface and the lower surface may or may not be parallel to each another. The light transmissive member 20 has one or more lateral surfaces that connect the upper surface and the lower surface. The one or more lateral surfaces are connected to the outer edge(s) of the upper surface and the outer edge(s) of the lower surface. The light transmissive member 20 has, for example, a rectangular-parallelepiped shape or cube shape. In this case, the light transmissive member 20 has rectangular upper surface and lower surface, and four rectangular lateral surfaces. The light transmissive member 20 does not have to have a rectangular-parallelepiped shape or cube shape. In other words, the top view shape of the light transmissive member 20 is not limited to rectangular, and can be any shape, such as circular, elliptical, or polygonal. Here, being “light transmissive” refers to having a transmittance of 80% or higher for the incident light. It does not have to have a light transmittance of 80% or higher for light of all wavelengths. The light transmissive member 20 may have a non-light transmissive region (region having no light transmittance) in part. The light transmissive member 20 is made of glass, for example. The light transmissive member 20 may be made of another light transmissive material, such as sapphire or quartz.

### Cap Member 1

In the cap member 1, the light transmissive member 20 is bonded to the upper surface 11 of the light shielding member 10 to close the opening of the light shielding member 10. In the case in which the light shielding member 10 is made of silicon and the light transmissive member 20 is made of glass, the light shielding member 10 can be anodically bonded to the light transmissive member 20, for example. The light transmissive member 20 may be bonded to the upper surface 11 of the light shielding member 10 via an adhesive. The bonding can be achieved by using a metal adhesive, for example. Examples of the metal adhesives include AuSn and metal paste. A resin adhesive may be used for the bonding.

A metal film 30 may be disposed on the lower surface 12 of the light shielding member 10. For the metal film 30, for example, Ti/Pt/Au (a metal film successively stacking Ti, Pt, and Au) can be used. In this case, the thickness of each of the Ti, Pt, and Au layers can be 0.05 μm to 2 μm, for example. For the metal film 30, Ni/Au (a metal film successively stacking Ni and Au), Cr/Pt/Au (a metal film successively stacking Cr, Pt, and Au), or the like may be used.

In the case of using the method of manufacturing a cap member 11 described later, the metal film 30 is formed only on the lower surface 12 of the light shielding member 10. The metal film 30 that is formed on the lower surface 12 is formed only on the lower surface 12. In other words, the metal film 30 formed on the lower surface 12 reaches neither the inner lateral surface 13 including the first region 13a and the second region 13b nor the outer lateral surfaces 14. The metal film 30 is formed to a position very close to the inner edges 12a of the lower surfaces 12, but does not reach the inner lateral surface 13 including the first region 13a and the second region 13b. As used herein, the expression “not reaching the inner lateral surface 13” includes the state in which 95% or more of the inner lateral surface 13 is not covered by the metal film 30. The distance from the metal film 30 to the inner edge 12a of the lower surface 12 is, for example, 0 to 1 μm. When the metal film 30 formed on the lower surface 12 reaches neither the inner lateral surface 13 nor the outer lateral surfaces 14, a metal adhesive 140 is less likely to reach the inner lateral surface 13 and the outer lateral surfaces 14 in the case of forming a light emitting device by bonding the cap member 1 to the substrate 110. If the metal adhesive 140 reaches at least one of the inner lateral surface 13 and the outer lateral surface 14, a shortage of the metal adhesive 140 on the lower surface 12 may occur, which may degrade the airtightness of the space that is enclosed by the cap member 1 and the substrate 110. With the metal film 30 reaching neither the inner lateral surface 13 nor the outer lateral surfaces 14, the airtightness of the space that is enclosed by the cap member 1 and the substrate 110 can be enhanced.

In the cap member 1, the inner lateral surface 13 of the light shielding member 10 has the first region 13a that extends from a corresponding inner edge 11a of the upper surface 11 toward the center 15c of the upper-surface-side opening 15a when viewed from above, and the second region 13b that extends from a corresponding inner edge 12a of the lower surface 12 toward the center 16c of the lower-surface-side opening 16a when viewed from below. This structure does not result in a shape in which a width of the light shielding member 10 is narrower at one of the upper surface 11 side and the lower surface 12 side and increases towards the other of the two sides as in the case of a conventional cap member which has only either the first region or the second region. Accordingly, the size of the cap member 1 in the width direction can be reduced as compared to a conventional cap member on the assumption that the width of the narrowest portion between two inner lateral surfaces 13 that face each other is the same as that of the conventional cap member. Accordingly, when the cap member 1 is used in an electronic device, such as a light emitting device, the electronic device can be miniaturized in the width direction. The inner lateral surfaces of a “conventional cap member” here are, for example, flat surfaces inclined at a certain inclination angle. The “width” here refers to the length in the direction that is parallel to the upper surface in a cross section that is orthogonal to the upper surface.

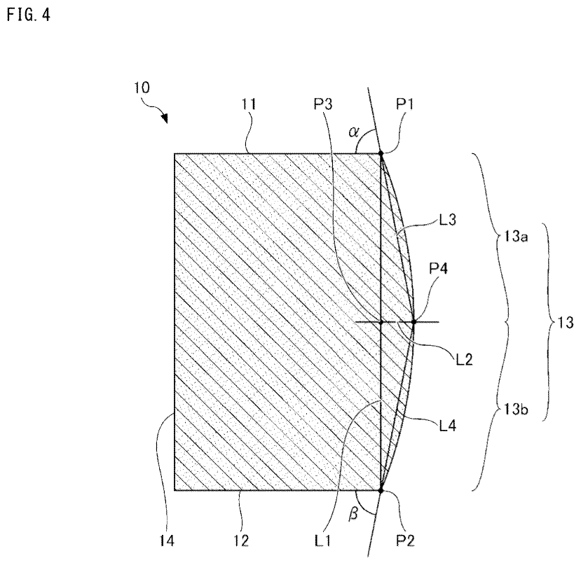

FIG. 4 is a partial cross-sectional view of the light shielding member which is a constituent element of the cap member shown in FIG. 1. As shown in FIG. 4, in the cross section orthogonal to the upper surface 11 of the light shielding member 10, the inner lateral surface 13 has a first connection point P1 that is connected to the upper surface 11, a second connection point P2 that is connected to the lower surface 12, and an intersecting point P4 that intersects with a second line L2 extending through a middle point P3 of a first straight line L1, which extends through the first connection point P1 and the second connection point P2, and the second line L2 is orthogonal to the first line L1.

An angle α formed by the upper surface 11 and the straight line L3 that extends through the first connection point P1 and the intersecting point P4, and an angle β formed by the lower surface 12 and the straight line L4 that extends through the second connection point P2 and the intersecting point P4 are preferably 55 degrees or greater but less than 90 degrees. With such a range of the angles, the length of the line segment (second line L2) connecting the intersecting point P4 and the middle point P3 can be reduced, so that the inner lateral surface 13 can be a shape that is close to a flat surface orthogonal to the upper surface 11. This allows for ensuring a large space inward of the inner lateral surface 13. In the case in which a certain length in the width direction is required for the inner space of the cap member 1, the inner lateral surface 13 is a shape that is close to a flat surface orthogonal to the upper surface 11, allowing for further miniaturizing the light shielding member 10 in the width direction. Accordingly, in the case of using the cap member 1 in an electronic device, such as a light emitting device, the dimension of the electronic device in the width direction can be further reduced. For example, the length of the inner edges 11a and 12a is a few millimeters per side, and the length of the line segment (second line L2) connecting the intersecting point P4 and the middle point P3 can be set to less than 300 μm.

In FIG. 4, in the region that includes the first connection point P1 and is enclosed by the straight line L1, the straight line L2, and the inner lateral surface 13, the area of a part enclosed by the straight line L1, the straight line L2, and the straight line L3 is larger than the area of the other part of the region. In the region that includes the second connection point P2 and is enclosed by the straight line L1, the straight line L2, and the inner lateral surface 13, the area of a part enclosed by the first straight line L1, the straight line L2, and the straight line L4 is larger than the area of the other part of the region.

### Method of Manufacturing Cap Member 1

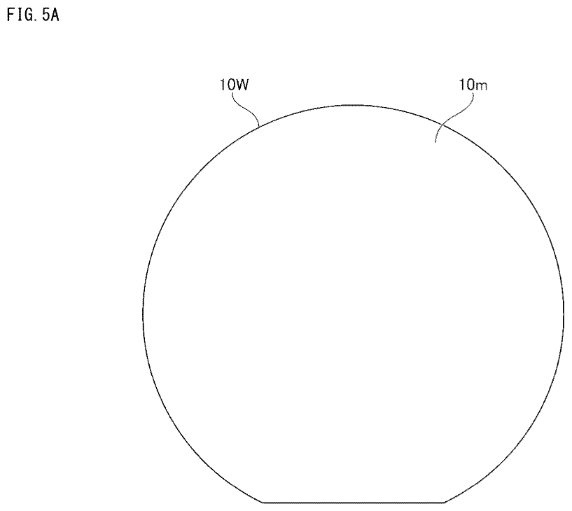

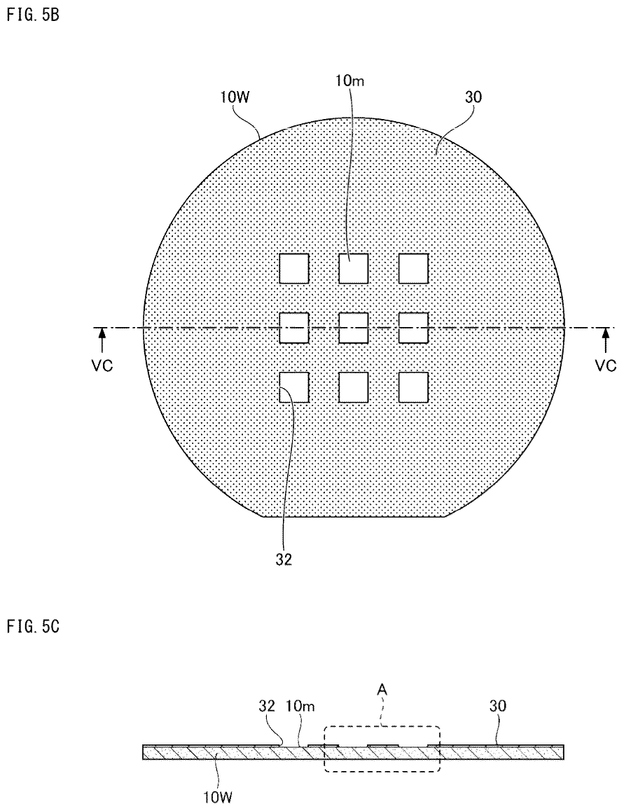

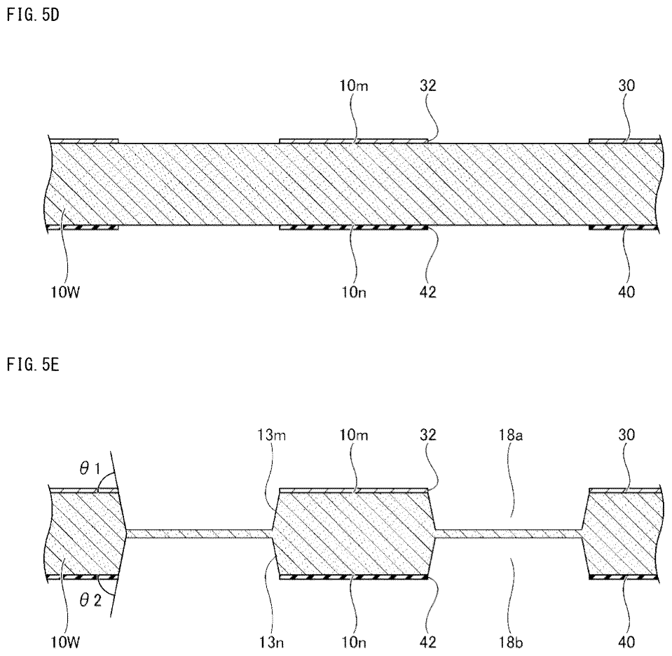

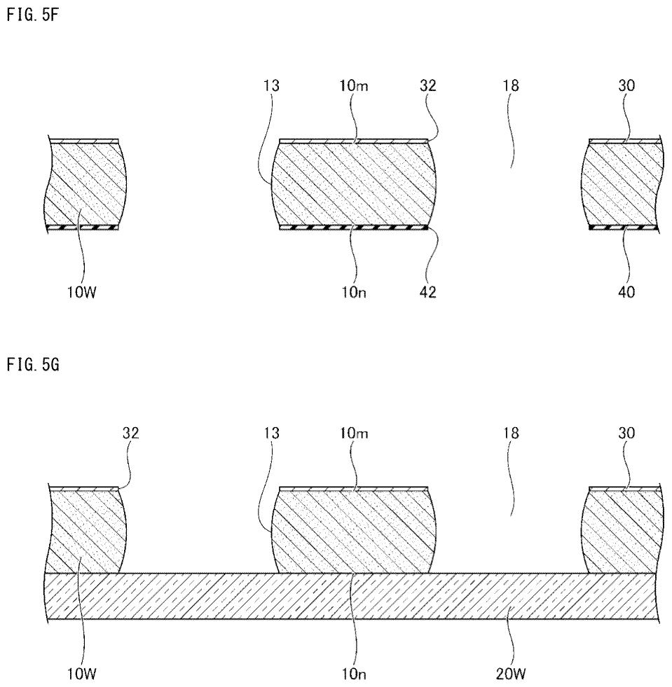

A method of manufacturing a cap member 1 according to the first embodiment will be explained with reference to FIGS. 5A-5H, inclusive. FIG. 5A to FIG. 5H include top views and cross-sectional views illustrating the method of manufacturing the cap member according to the first embodiment.

### Providing Light Shielding Member

First, as shown in FIG. 5A, a sheet-shaped light shielding member 10W is provided. The light shielding member 10W is, for example, a silicon substrate having a first principal surface 10m which is {100} plane. Here, {100} plane refers to all planes including the (100) plane, which is one of the crystal lattice planes in the diamond structure, which is a crystal structure stable at room temperature and normal pressure, of silicon and its equivalent planes. Equivalent planes refer to those that are defined by the Miller indices. The first principal surface of a silicon substrate may be oriented at an off-angle of about ±2 degrees relative to {100} plane. The off-angle is preferably ±1 degrees, more preferably ±0.2 degrees.

The size and the thickness of the light shielding member 10W can be suitably adjusted depending on the use of the cap member to be obtained. Multiple cap members 1 are preferably obtained from one light shielding member 10W, and for this purpose, the light shielding member 10W preferably has a length and/or width of several centimeters to several tens of centimeters.

In the light shielding member 10W, the first principal surface 10m and the opposing second principal surface are preferably both {100} planes. In other words, the light shielding member 10W preferably has a second principal surface that is parallel to the first principal surface 10m. The thickness of the light shielding member 10W is preferably uniform, but may have a different width in part. The thickness of the light shielding member 10W can be set, for example, to 100 to several thousand micrometers, for example, 500 to 2000 μm.

### Disposing Metal Film

Next, a metal film 30 having first openings 32 in which the first principal surface 10m is exposed is disposed on the first principal surface 10m of the light shielding member 10W as shown in FIG. 5B and FIG. 5C. In FIG. 5B, the metal film 30 is shown using a dot pattern for explanation purposes. Specifically, for example, a mask is formed to cover the areas where first openings 32 will be formed on the first principal surface 10m of the light shielding member 10W. Then the metal film 30 is formed by sputtering or the like over the mask. The mask is subsequently removed. Here, as one example, the first openings 32 are rectangular when viewed from above.

For the metal film 30, for example, Ti/Pt/Au (a metal film successively stacking Ti, Pt, and Au) can be used. In this case, the thickness of each of Ti, Pt, and Au layers can be set to 0.05 μm to 2 μm, for example. For the metal film 30, Ni/Au (a metal film successively stacking Ni and Au), Cr/Pt/Au (a metal film successively stacking Cr, Pt, and Au), or the like may be used.

FIG. 5B is a plan view and FIG. 5C is a cross-sectional view taken along the line VC-VC in FIG. 5B. In the explanation below, the partial cross-sectional view corresponding to the portion A enclosed by a broken line in FIG. 5C will be used.

### Disposing Cover Film

Next, as shown in FIG. 5D, a cover film 40 is disposed on the second principal surface 10n of the light shielding member 10W. The cover film 40 has second openings 42, in which the second principal surface 10n is exposed, formed at locations that overlap the first openings 32 when viewed from the first principal surface 10m side. The material for the cover film 40 is not particularly limited so long as it is resistant to the etching solution used in forming through holes subsequently. For example, a silicon oxide film or silicon nitride film can be used. A silicon oxide film or silicon nitride film can be easily removed after an etching process, as compared to the metal film 30, thereby facilitating the bonding with the light transmissive member 20W. Specifically, for example, a mask is disposed on the second principal surface 10n of the light shielding member 10W to cover the regions where second openings 42 will be formed. Then the cover film 40 is formed over the mask by sputtering, CVD, or the like. The mask is removed subsequently. The shapes of the second openings 42 are preferably the same as those of the first openings 32, but not limited thereto.

### Forming Through Hole

Then, as shown in FIG. 5E and FIG. 5F, the light shielding member 10W is etched from the first principal surface 10m side and the second principal surface 10n side while using the metal film 30 and the cover film 40 as etching masks, thereby forming through holes 18 that extends from the first openings 32 to the second openings 42. For this etching process, isotropic etching can be employed. Wet etching is preferable. Wet etching can be performed on multiple light shielding members 10W simultaneously, thereby allowing an increase in production efficiency.

In forming a through hole, a first recess 18a formed from the metal film 30 side and a second recess 18b formed from the cover film 40 side are connected together to form the through hole 18. FIG. 5E shows a state in the middle of the etching process, specifically, the state immediately before the first recess 18a and the second recess 18b are connected together. FIG. 5F shows the state in which the etching has completed, i.e., a through hole 18 has been created as a result of continuing etching from the state shown in FIG. 5E.

That is, in the step of forming a through hole, the first recess 18a and the second recess 18b are connected with each other, and the etching is continued even after the connection of these recesses. Accordingly, an inner lateral surface(s) formed of the inner lateral surface(s) 13m of the first recess 18a and the inner lateral surface(s) 13n of the second recess 18b connected together is further etched in the width direction from the state at the time of the connection of the recesses, thereby forming the inner lateral surface(s) 13 of a cap member.

In the case in which the light shielding member 10W is a silicon substrate having a first principal surface 10m that is {100} plane, in the step of forming a through hole 18, the first recess 18a with an inner lateral surface 13m which is {111} plane oblique to {100} plane and a second recess 18b with an inner lateral surface 13n which is {111} plane oblique to {100} plane are formed as shown in FIG. 5E. The first recess 18a and the second recess 18b are truncated pyramids that oppose one another.

By allowing the first recess 18a the second recess 18b to be connected with each other and continuing etching even after that, the inner lateral surface 13m, formed of {111} plane, of the first recess 18a and the inner lateral surface 13n, formed of {111} plane, of the second recess 18b are further etched in the width direction, resulting in formation of an inner lateral surface 13 curved in a cross-sectional view orthogonal to the first principal surface 10m as shown in FIG. 5F. With the inner lateral surface 13 curved in a cross section, a larger space can be ensured inward of the inner lateral surface 13 as compared to the case in which the inner lateral surface is straight.

In the case in which the light shielding member 10W is a silicon substrate, for example, anisotropic etching using a potassium hydroxide (KOH) aqueous solution can be employed as an etching solution. At this time, in the case in which the first principal surface 10m of the light shielding member 10W is {100} plane, an inner lateral surfaces 13m and 13n made of flat {111} planes are formed in the middle of the etching process as shown in FIG. 5E. An angle θ1 formed by the first principal surface 10m and the inner lateral surface 13m and an angle θ2 formed by the second principal surface 10n and the inner lateral surface 13n are about 54.7°. For the etching solution, a tetramethylammonium hydroxide (TMAH) aqueous solution or a sodium hydroxide (NaOH) aqueous solution can be alternatively used.

As described above, in the step of forming a through hole, etching masks having openings are disposed on the first principal surface 10m and the second principal surface 10n such that corresponding ones of openings of the etching masks face each other. Then the light shielding member 10W is subjected to etching from the first principal surface 10m side and the second principal surface 10n side. A through hole 18 is created when the first recess 18a formed from the first principal surface 10m side and the second recess 18b formed from the second principal surface 10n are connected to each other.

Accordingly, this does not result in a shape in which one of its width at the first principal surface 10m side and its width at the second principal surface 10n side is narrower and the width increases towards the other of them as in a case of using a conventional technique of etching only from one side. Accordingly, when the cap member 1 is compared to a conventional cap member assuming that the width of the narrowest portion between two opposing inner lateral surfaces 13 of the cap member 1 is the same as that of the conventional cap member, a size of the cap member 1 in the width direction can be reduced as compared to the conventional cap member. As such, using the cap member 1 in an electronic device, such as a light emitting device, can miniaturize the electronic device in the width direction.

For the etching mask for the first principal surface 10m side of the light shielding member 10W, a metal film 30, not a silicon oxide film or the like, is used. In the case of using a silicon oxide film or the like for the etching mask on the first principal surface 10m side of the light shielding member 10W, the first recess 18a larger than the opening of the silicon oxide film or the like would be formed when etching continues after creating a through hole. In contrast, in the case of using a metal film 30 as an etching mask on the first principal surface 10m side, a first recess 18a having substantially the same size as the opening of the metal film 30 can be formed even when etching continues after forming a through hole. The distance from the metal film 30 to the inner edge of the first recess 18a in the first principal surface 10m after forming the first recess 18a is, for example, in a range of 0 to 1 μm. As described above, using a metal film 30 for the etching mask on the first principal surface 10m side facilitates the formation of a first recess 18 having the size as designed.

### Disposing Light Transmissive Member

Next, as shown in FIG. 5G, a sheet-shaped light transmissive member 20W is disposed on the second principal surface 10n of the light shielding member 10W to close the through holes 18. Specifically, the light transmissive member 20W is disposed on and bonded to the second principal surface 10n of the light transmissive member 10W by anodic bonding, for example. For the method of bonding the second principal surface 10n of the light shielding member 10W and the light transmissive member 20W, the room temperature bonding or the hydrophilic bonding can be used. A step of removing the cover film 40 may be included between the step of forming a through hole 18 and the step of disposing a light transmissive member 20W. The removal of the cover film 40 can enhance the bonding strength between the second principal surface 10n of the light shielding member 10W and the light transmissive member 20W.

### Cutting

Next, as shown in FIG. 5H, the light shielding member 10W, the light transmissive member 20W, and the metal film 30 are cut after the step of disposing the light transmissive member 20W. Consequently, the light shielding member 10W and the light transmissive member 20W are separated into light shielding members 10 and light transmissive members 20, thereby producing multiple cap members 1. For cutting, for example, a blade, laser, or the like can be used.

As described above, in the method of manufacturing a cap member 1, excessive etching in the width direction can be inhibited even when etching continues after the formation of a through hole, thereby facilitating control of the etching. Also, in a cap member 1 produced by such a manufacturing method does not have a shape in which a portion corresponding to the central portion of the lateral surface(s) is thinnest although the etching has been continued even after the creation of a through hole, so that a sufficient strength can be maintained.

### First Variation of Method of Manufacturing Cap Member According to First Embodiment

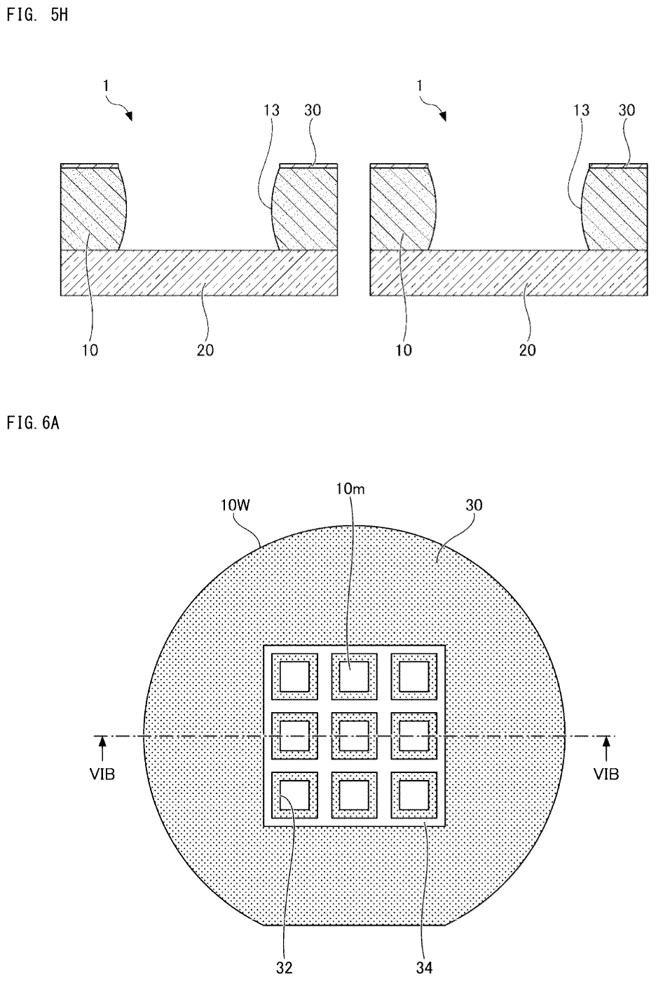

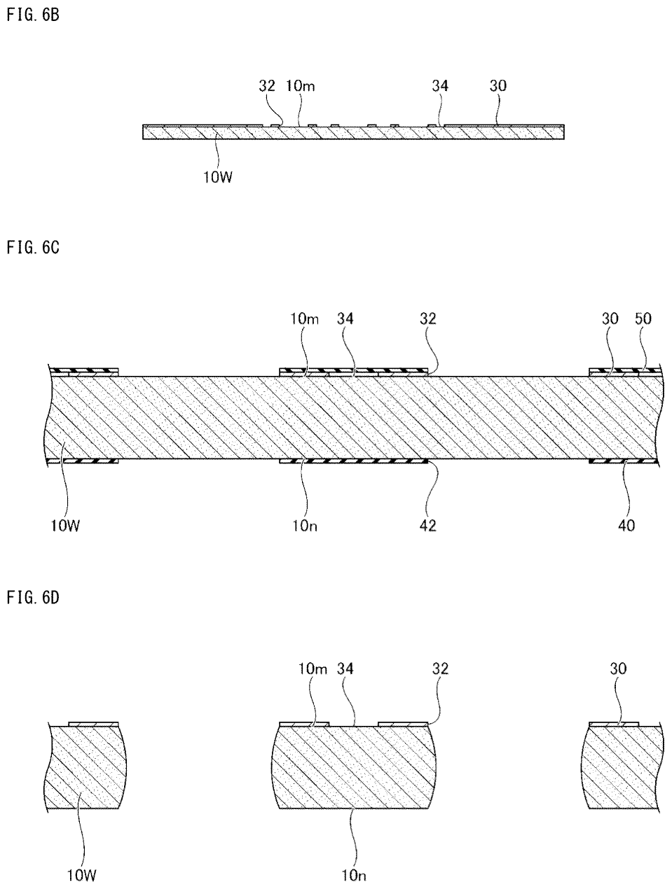

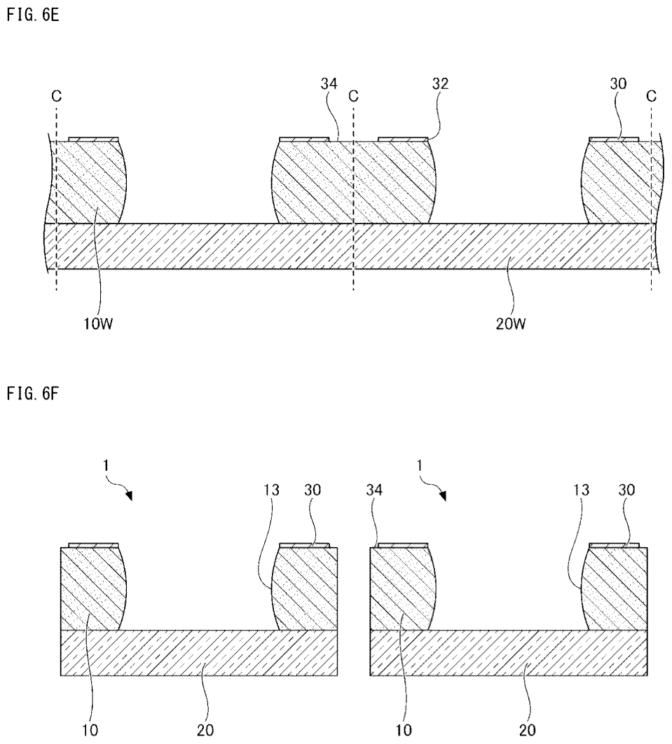

As shown in FIG. 6A and FIG. 6B, in the step of forming a metal film 30, a metal film 30 having a plurality of first openings 32 and grooves 34 where each of the grooves 34 surrounds a respective one of the first openings 32 and from which the first principal surface 10m is exposed may be formed on the first principal surface 10m of the light shielding member 10W. The first openings 32 and the grooves 34 may be formed at the same time or different times. The metal film 30 that forms the first openings 32 and the metal film 30 that forms the grooves 34 may be formed of the same material or different materials. The method further includes a step of cutting the light shielding member 10W and the light transmissive member 20W along the grooves 34 at locations indicated by the broken lines C in FIG. 6E after the step of disposing a light transmissive member 20W.

In this case, it is preferable to include a step of forming a cover film 50 on the metal film 30 to cover the grooves 34 without covering the first openings 32, as shown in FIG. 6C, between the step of forming a metal film 30 and the step of forming a through hole 18. The method further includes a step of removing the cover film 50 present on the metal film 30, as shown in FIG. 6D, between the step of forming a through hole 18 and the step of cutting.

Cutting the light shielding member 10W and the light transmissive member 20W along the grooves 34 in this manner can eliminate the needs of cutting the metal film 30. This can prevent generation of burrs as shown in FIG. 6F, which can increase the yield. Furthermore, when employing dicing, this allows for extending the service life of a blade. Moreover, performing the step of forming a cover film 50 that covers the grooves 34 without covering the first openings 32 allows for performing etching in the step of forming a through hole 18 in the state in which the grooves 34 are covered by the cover film 50, resulting in preventing the grooves 34 from being etched. This can reduce the possibility of detachment of the metal film 30 originating from a groove 34 during the step of forming a through hole 18.

### Second Variation of Method of Manufacturing Cap Member According to First Embodiment

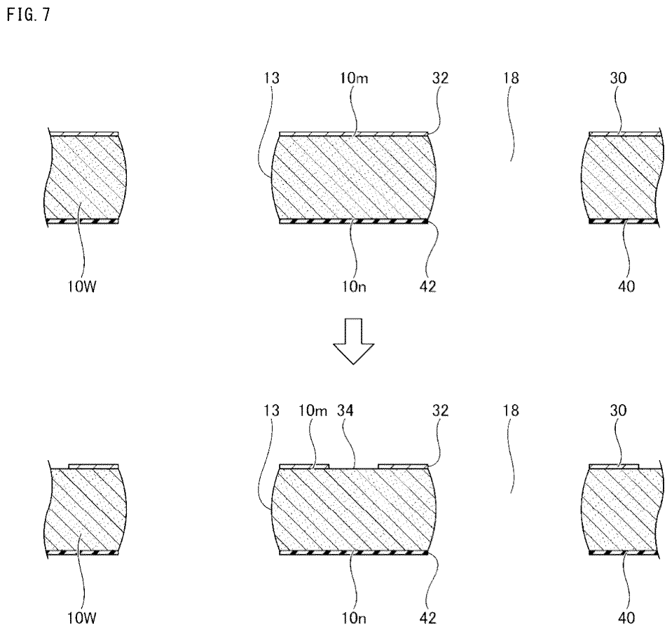

In the case of not forming grooves 34 in the step of forming a metal film 30, grooves 34 each of which surrounds a respective one of the first openings 32 and from which the first principal surface 10m is exposed may be formed in the metal film 30 as shown under the arrow in FIG. 7 after the step of forming a through hole 18 shown above the arrow in FIG. 7. In this case, the method further includes a step of cutting the light shielding member 10W and the light transmissive member 20W along the grooves 34 as in FIG. 6E after the step of disposing a light transmissive member 20W. For forming the grooves 34, for example, a laser processing can be employed.

When using this method, no grooves 34 exist during the step of forming a through hole 18. Accordingly, the metal film 30 is not likely to detach in the step of forming a through hole 18. Thus, a step of forming a cover film 50 shown in FIG. 6C is not needed. Further, cutting the light shielding member 10W and the light transmissive member 20W along the grooves 34 can eliminate the needs of cutting the metal film 30, so that generation of burrs can be prevented, resulting in increase of the yield. Furthermore, when employing dicing, this can extend the service life of a blade.

### Second Embodiment

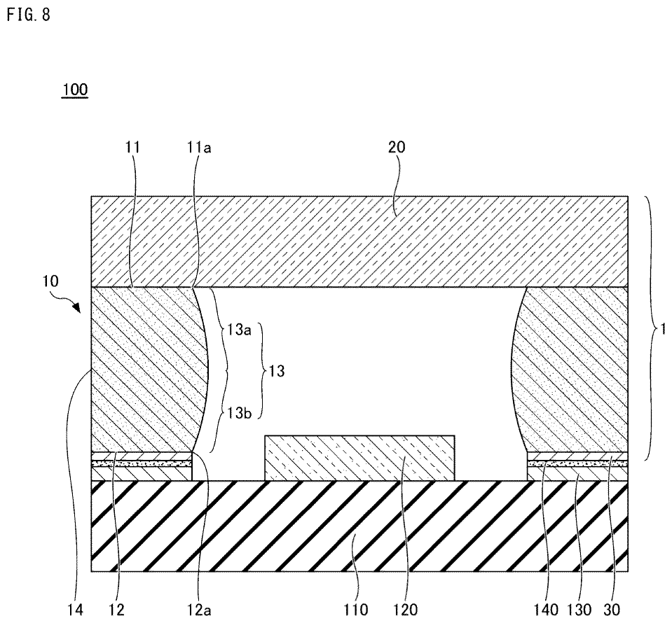

As a second embodiment, an example of a light emitting device which includes a cap member of the first embodiment will be described. FIG. 8 is a cross-sectional view illustrating a light emitting device according to the second embodiment. As shown in FIG. 8, the light emitting device 100 according to the second embodiment has a substrate 110, a light emitting element 120, and a cap member 1 of the first embodiment.

### Substrate 110

A substrate 110 has an upper surface and a lower surface. The upper surface may be parallel to the lower surface or not. The substrate 110 has one or more lateral faces that connect the upper surface and the lower surface. The one or more lateral surfaces connect the outer edge(s) of the upper surface and the outer edge(s) of the lower surface. The substrate 110 has a rectangular-parallelepiped shape or cube, for example. In this case, the upper surface and the lower surface are both rectangular, and the substrate 110 has four rectangular lateral surfaces. For example, the substrate 110 may be a sheet having a given shape when viewed from above.

The substrate 110 contains an insulation material, for example. The substrate 110 can be formed by using a ceramic as a main material, for example. For the ceramic, for example, aluminum nitride, silicon nitride, aluminum oxide, or silicon carbide can be used. The main material for forming the substrate 110 may be a conductive material. Examples include metals, such as aluminum, gold, silver, copper, tungsten, iron, nickel, cobalt, or their alloys, diamond, and composite materials such as a copper-diamond composite.

### Light Emitting Element 120

A light emitting element 120 is, for example, a semiconductor laser element. The semiconductor laser element may be an edge emitting laser or vertical cavity surface emitting laser (VCSEL). The light emitting element 120 is not limited to a semiconductor layer element, and can be, for example, a light emitting diode (LED), organic light emitting diode (OLED), or the like.

For the light emitting element 120, a light emitting element which emits visible light can be used. Examples of visible light emitting elements include a blue light emitting element, green light emitting element, and red light emitting element. Here, a blue light emitting element, green light emitting element, and red light emitting element refer to those emitting light having peak emission wavelengths of 405 nm to 494 nm, 495 nm to 570 nm, and 605 nm to 750 nm, respectively. Examples of light emitting elements 120 emitting blue or green light include semiconductor laser elements containing a nitride semiconductor. For the nitride semiconductor, for example, GaN, InGaN, or AlGaN can be used. Examples of light emitting elements 120 which emit red light include semiconductor laser elements containing an InAlGaP-based, GaInP-based, GaAs-based, or AlGaAs-based semiconductor.

The peak emission wavelength of the light emitted by the light emitting element 120 does not have to be limited to those described above. For example, the light emitted by the light emitting element 120 may be visible light of a color different from those described above. Besides visible light emitting elements, a light emitting element that emits ultraviolet light, infrared light, or the like may be used.

### Light Emitting Device 100

In a light emitting device 100, the light emitting element 120 is disposed on the upper surface of the substrate 110. The light emitting element 120 can be disposed such that an emission surface of the light emitting element 120 faces the lower surface side of the light transmissive member 20, for example. In the peripheral portion of the upper surface of the substrate 110, a metal film 130 is disposed to enclose the light emitting element 120 when viewed from above, for example. The metal film 130 can have a similar composition to that of the metal film 30, for example.

The lower surface 12 of the light shielding member 10 which is a constituent of the cap member 1 is bonded to the peripheral portion of the upper surface of the substrate 110. More specifically, the metal film 30 disposed on the lower surface 12 of the light shielding member 10 and the metal film 130 disposed in the peripheral portion of the upper surface of the substrate 110 are bonded by a metal adhesive 140. For the metal adhesive 140, for example, AuSn can be used.

This creates a sealed space enclosed by the substrate 110 and the cap member 1, and the light emitting element 120 is disposed in this sealed space. The sealed space may be hermetically sealed. A hermetically sealed space can reduce the collection of organic dust on the emission surface of the light emitting element 120.

In the case of using an edge emitting laser for the light emitting element 120, for example, it is preferably disposed in a hermetically sealed space as the emission surface readily attracts organic dust. In the case of using a light emitting element that emits light having a shorter wavelength than green for the light emitting element 120, it is preferably disposed in a hermetically sealed space as the emission surface readily attracts organic dust. Accordingly, it is particularly preferable to place the light emitting element 120 in a hermetically sealed space when an edge emitting laser that emits light having a shorter wavelength than green is used as the light emitting element 120.

The light transmissive member 20 which is a constituent of the cap member 1 allows the light emitted by the light emitting element 120 to transmit therethrough to the outside. The lower surface of the light transmissive member 20 serves as the light incident surface for the light emitted by the light emitting element 120. The upper surface of the light transmissive member 20 serves as the emission surface through which the light entering the light incident surface exits out of the light emitting device 100.

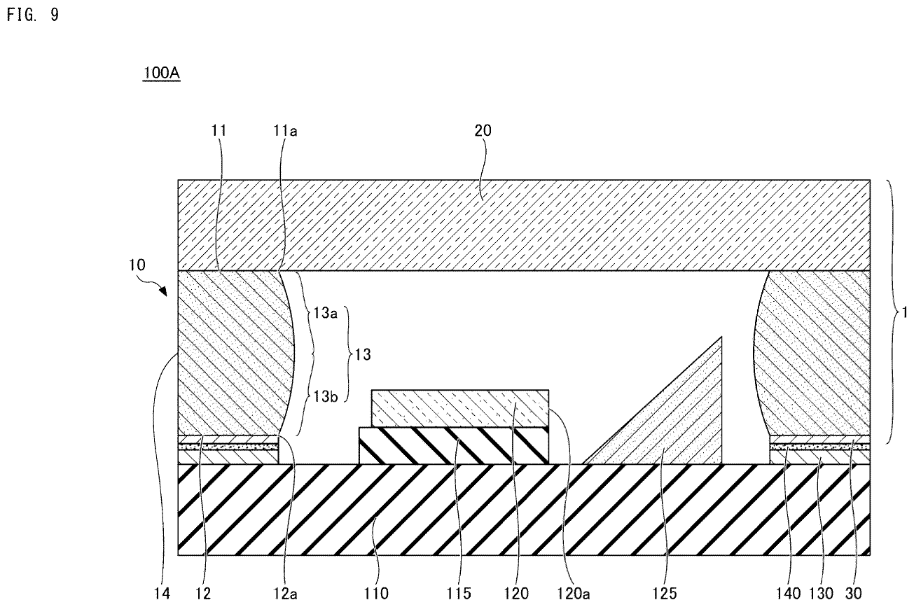

As in the case of the light emitting device 100A shown in FIG. 9, the light emitting element 120 may be disposed on the substrate 110 such that the emission surface 120a is oriented towards an inner lateral surface 13 of the light shielding member 10, for example. In this case, on the substrate 110 between the emission surface 120a of the light emitting element 120 and the inner lateral surface 13 of the light shielding member 10, a reflecting member 125 that reflects the light emitted by the light emitting element 120 towards the light incident surface of the light transmissive member 20 is disposed. The reflecting member 125 can have an inclined surface, inclined at, e.g., 45 degrees, on which a metal film is formed.

The use of a cap member 1 miniaturized in the width direction in the light emitting device 100 can miniaturize the light emitting device 100 in the width direction as a whole. The light emitting device 100 can be used in an automotive headlight, for example. Not limited to this, the light emitting device 100 can be utilized as the light source of a lighting fixture, projector, backlight of a head mounted display and any other display. This also applies to the light emitting device 100A.

In the foregoing, preferable embodiments of the invention have been described in detail. The present invention, however, is not restricted by these embodiments, and various modifications and substitutions can be made to those described above without deviating from the scope of the claims.

What is claimed is:

1. A cap member comprising:
a frame-shaped light shielding member having an upper surface, a lower surface, and one or more inner lateral surfaces connecting a corresponding one of one or more inner edges of the upper surface and a corresponding one of one or more inner edges of the lower surface;
a light transmissive member bonded to an upper surface side of the light shielding member and closing an opening of the light shielding member; and
a metal film disposed on the lower surface of the light shielding member,
wherein an inner lateral surface of the one or more inner lateral surfaces of the light shielding member include:
a first region extending from the inner edge of the upper surface of the light shielding member toward the center of an upper-surface-side opening, defined by the one or more inner edges of the upper surface, when viewed from above the cap member, and
a second region extending from the inner edge of the lower surface of the light shielding member toward the center of a lower-surface-side opening, defined by the one or more inner edges of the lower surface, when viewed from below the cap member, and
wherein the metal film does not reach the inner lateral surface of the light shielding member including the first region and the second region.

2. The cap member according to claim 1, wherein
the first region of each of the one or more inner lateral surfaces extends from a respective one of the one or more inner edge of the upper surface toward the center of the upper-surface-side opening throughout the total length of the respective inner edge of the upper surface when viewed from above the cap member, and
the second region of each of the one or more inner lateral surfaces extends from a respective one of the one or more inner edges of the lower surface toward the center of the lower-surface-side opening throughout the total length of the respective inner edge of the lower surface when viewed from below the cap member.

3. The cap member according to claim 1 wherein the inner lateral surface is curved in a cross-sectional view orthogonal to the upper surface of the light shielding member.

4. The cap member according to claim 1 wherein, in a cross-sectional view orthogonal to the upper surface of the light shielding member, the inner lateral surfaces has
a first connection point that is connected to the upper surface,
a second connection point that is connected to the lower surface, and
an intersecting point that intersects with the second line extending through the middle point of a first straight line, which extends through the first connection point and the second connection point, and being orthogonal to the first straight line,
an angle formed by the upper surface and the straight line that extends through the first connection point and the intersecting point and an angle formed by the lower surface and a straight line that extends through the second connection point and the intersecting point are each 55 degrees or larger but smaller than 90 degrees.

5. The cap member according to claim 1 wherein the light shielding member is made of silicon and the light transmissive member is made of glass.

6. The cap member according to claim 1 wherein the distance from the metal film to the one or more inner edges of the lower surface is 0 to 1 μm.

7. A light emitting device comprising:
a substrate;
a light emitting element disposed on an upper surface of the substrate; and
a cap member according to any one of claim 1,
wherein a lower surface of the light shielding member is bonded to a peripheral portion of the upper surface of the substrate, and
wherein the light emitting element is sealed by the substrate and the cap member.

8. A method of manufacturing a cap member, the method comprising:
providing a sheet-shaped light shielding member;
disposing, on a first principal surface of the light shielding member, a metal film having a first opening in which the first principal surface is exposed;
disposing, on a second principal surface of the light shielding member, a cover film having a second opening in which the second principal surface is exposed, the second opening formed at a position that overlaps the first opening when viewed from the first principal surface side;
forming a through hole that extends from the first opening to the second opening by etching the light shielding member from the first principal surface side and the second principal surface side; and
disposing, on the second principal surface of the light shielding member, a sheet-shaped light transmissive member that closes the through hole,
wherein, in the forming the through hole, the through hole is formed as a result of allowing a first recess formed from the metal film side and a second recess formed from the cover film side to be connected with each other.

9. The method of manufacturing a cap member according to claim 8 further comprising removing the cover film between the forming the through hole and the disposing the sheet-shaped light transmissive member.

10. The method of manufacturing a cap member according to claim 8 wherein
in the forming the through hole, after the first recess and the second recess are connected, the etching is continued to further etch an inner lateral surface, formed of the inner lateral surface of the first recess and the inner lateral surface of the second recess, from a state at the time of the connection to thereby form an inner lateral surface of the cap member.

11. The method of manufacturing a cap member according to claim 8 wherein
the light shielding member is a silicon substrate in which the first principal surface is {100} plane, and
in the forming the through hole,
the first recess defined by {111} plane oblique to the {100} plane and the second recess defined by {111} plane oblique to the {100} plane are connected to each other, and
the {111} plane of the first recess and the {111} plane of the second recess are further etched by continuing the etching even after the recesses are connected, thereby forming a curved inner lateral surface in a cross section orthogonal to the first principal surface.

12. The method of manufacturing a cap member according to claim 8 wherein
in the disposing the metal film, a metal film is formed on the first principal surface of the light shielding member, the metal film having a plurality of the first openings and grooves each of which surrounds a respective one of the first openings and from which the first principal surface is exposed,
the method further comprises, after the disposing the light transmissive member, cutting the light shielding member and the light transmissive member along the grooves.

13. The method of manufacturing a cap member according to claim 9 wherein
in the disposing the metal film, a metal film is formed on the first principal surface of the light shielding member, the metal film having a plurality of the first openings and grooves each of which surrounds a respective one of the first openings and from which the first principal surface is exposed,
the method further comprises, after the disposing the light transmissive member, cutting the light shielding member and the light transmissive member along the grooves.

14. The method of manufacturing a cap member according to claim 10 wherein
in the disposing the metal film, a metal film is formed on the first principal surface of the light shielding member, the metal film having a plurality of the first openings and grooves each of which surrounds a respective one of the first openings and from which the first principal surface is exposed,
the method further comprises, after the disposing the light transmissive member, cutting the light shielding member and the light transmissive member along the grooves.

15. The method of manufacturing a cap member according to claim 11 wherein
in the disposing the metal film, a metal film is formed on the first principal surface of the light shielding member, the metal film having a plurality of the first openings and grooves each of which surrounds a respective one of the first openings and from which the first principal surface is exposed,
the method further comprises, after the disposing the light transmissive member, cutting the light shielding member and the light transmissive member along the grooves.

16. The method of manufacturing a cap member according to claim 12, further comprising:
between the disposing the metal film and the forming the through hole, forming, on the metal film, a cover film that covers the grooves and does not cover the first opening, and
between the forming the through hole and the cutting, removing the cover film present on the metal film.

17. The method of manufacturing a cap member according to claim 13, further comprising:
between the disposing the metal film and the forming the through hole, forming, on the metal film, a cover film that covers the grooves and does not cover the first opening, and
between the forming the through hole and the cutting, removing the cover film present on the metal film.

18. The method of manufacturing a cap member according to claim 14, further comprising:
between the disposing the metal film and the forming the through hole, forming, on the metal film, a cover film that covers the grooves and does not cover the first opening, and
between the forming the through hole and the cutting, removing the cover film present on the metal film.

19. The method of manufacturing a cap member according to claim 15, further comprising:
between the disposing the metal film and the forming the through hole, forming, on the metal film, a cover film that covers the grooves and does not cover the first opening, and
between the forming the through hole and the cutting, removing the cover film present on the metal film.
